(19) United States
(12) Patent Application Publication
(10) Pub. No.: US 2024/0377467 A1
(43) Pub. Date: Nov. 14, 2024

(54) POWER SUPPLY CIRCUIT

(71) Applicant: Hamilton Sundstrand Corporation, Charlotte, NC (US)

(72) Inventor: Andrew McLean, Halesowen (GB)

(21) Appl. No.: 18/658,247

(22) Filed: May 8, 2024

(30) Foreign Application Priority Data
May 9, 2023 (EP) 23172450.1

(51) Int. Cl. G01R 31/392; G01R 31/389; H02J 7/00; H02J 9/06

(52) U.S. Cl. CPC G01R 31/392; G01R 31/389; H02J 7/0063; H02J 9/061; H02J 2207/20

(57) ABSTRACT

A power supply circuit includes a series connection, the series connection being configured to transmit energy from a main energy source to an output and an energy storage device connected in parallel to the series connection, the energy storage device being chargeable via the main energy source during a charging mode. The energy storage device is configured to supply energy to the output during a failure of the main energy source; and a controller configured to monitor and/or test the energy storage device for degradation when the energy storage device is not supplying energy to the output and when the energy storage device is not being charged.

### CROSS REFERENCE TO RELATED APPLICATIONS

This application claims priority to European Patent Application No. 23172450.1 filed May 9, 2023, the entire contents of which is incorporated herein by reference.

### FIELD OF THE INVENTION

This disclosure relates to a power supply circuit.

### BACKGROUND

Power supply circuits provide electrical energy to electronic systems. It is desirable to improve power supply circuits, and in particular, prevent failures in power supply circuits.

### SUMMARY

According to a first aspect, there is provided a power supply circuit comprising: a series connection, the series connection being configured to transmit energy from a main energy source to an output; an energy storage device connected in parallel to the series connection, the energy storage device being chargeable via the main energy source during a charging mode, the energy storage device being configured to supply energy to the output during a failure of the main energy source; and a controller configured to monitor and/or test the energy storage device for degradation when the energy storage device is not supplying energy to the output and when the energy storage device is not being charged. By monitoring and/or testing the energy storage device, degradation of the energy storage device can be detected prior to failure of the device, so that action can be taken to prevent the power supply circuit from failing.

The controller may be configured to monitor and/or test the energy storage device by measuring the rate at which the energy storage device discharges when the energy storage device is connected to a fixed load.

The controller may be configured to determine whether the rate at which the energy storage device discharges is within a threshold rate of discharge.

The threshold rate of discharge may be based on the fixed load. The threshold rate of discharge may be a maximum rate of discharge before failure of the energy storage device occurs.

The controller may be configured to determine that the energy storage device is degrading when the rate at which the energy storage device discharges is greater than the threshold rate of discharge.

The controller may be configured to monitor and/or test the energy storage device by measuring the effective series resistance of the energy storage device when the energy storage device is connected to a pulsed load.

The controller may be configured to determine whether the effective series resistance is within a threshold effective series resistance.

The threshold effective series resistance may be based on a voltage change of the energy storage device when the energy storage device is connected to the pulsed load. The voltage change may be an instantaneous voltage change. The threshold effective series resistance may be a maximum effective series resistance before failure of the energy storage device occurs.

The controller may be configured to determine that the energy storage device is degrading when the effective series resistance of the energy storage device is greater than the threshold effective series resistance.

The controller may be configured to monitor and/or test the energy storage device by measuring a change in an energy level and/or voltage of the energy storage device when no load is connected across the energy storage device.

The controller may be configured to determine that the energy storage device is degrading when the change in the energy level and/or voltage of the energy storage device is greater than a threshold value.

The threshold value may be a maximum change in the energy level and/or voltage of the energy storage device before failure of the energy storage device occurs.

The controller may be configured to predict a remaining life of the energy storage device based on the monitoring and/or testing.

The controller may be configured to predict a remaining life of the energy storage device by comparing the rate at which energy discharges from the energy storage device to an initial rate of discharge. The initial rate of discharge may be the rate at which the energy storage device discharges during an initial monitoring and/or testing of the energy storage device.

The controller may be configured to predict a remaining life of the energy storage device by comparing the effective series resistance of the energy storage device to an initial effective series resistance. The initial effective series resistance may be the effective series resistance of the energy storage device during an initial monitoring and/or testing of the energy storage device.

The controller may be configured to predict a remaining life of the energy storage device by determining a difference between the change in the energy level and/or voltage of the energy storage device to an initial value. The initial value may be the change in the energy level and/or voltage of the energy storage device during an initial monitoring and/or testing of the energy storage device.

The fixed load may be resistor.

The energy storage device may be connected in parallel to the series connection via a diode. The diode may be configured to prevent the energy storage device from supplying energy to the output when there is no failure of the main energy source.

The energy storage device may be connected in parallel to the series connection via a switch. The switch may be closed during the charging mode. The switch may be open when the energy storage device is not being charged.

The energy storage device may be configured to, during a failure of the main energy source, supply energy to the output via the diode.

The power supply circuit may further comprise a first voltage converter and a second voltage converter connected in series. The energy storage device may be connected in parallel to the first voltage converter and the second voltage converter.

The first voltage converter and the second voltage converter may be configured to step down the voltage supplied by the main energy source.

The first voltage converter may comprise a flyback converter.

The second voltage converter may comprise a buck converter.

The energy storage device may be supplied with a higher voltage than the output.

The second voltage converter may be configured to supply the energy storage device with a higher voltage than the output.

The power supply circuit may further comprise an electromagnetic capability (EMC) filter.

### BRIEF DESCRIPTION OF THE DRAWINGS

Embodiments will be further described and explained by way of example with reference to the accompanying drawings in which:

FIG. 1 shows a schematic of a power supply circuit;

FIG. 2a shows a graph of the rate of discharge of an energy storage device;

FIG. 2b shows a graph of the rate of discharge of an energy storage device;

FIG. 3a shows a graph of the effective series resistance of an energy storage device; and

FIG. 3b shows a graph of the effective series resistance of an energy storage device.

### DETAILED DESCRIPTION

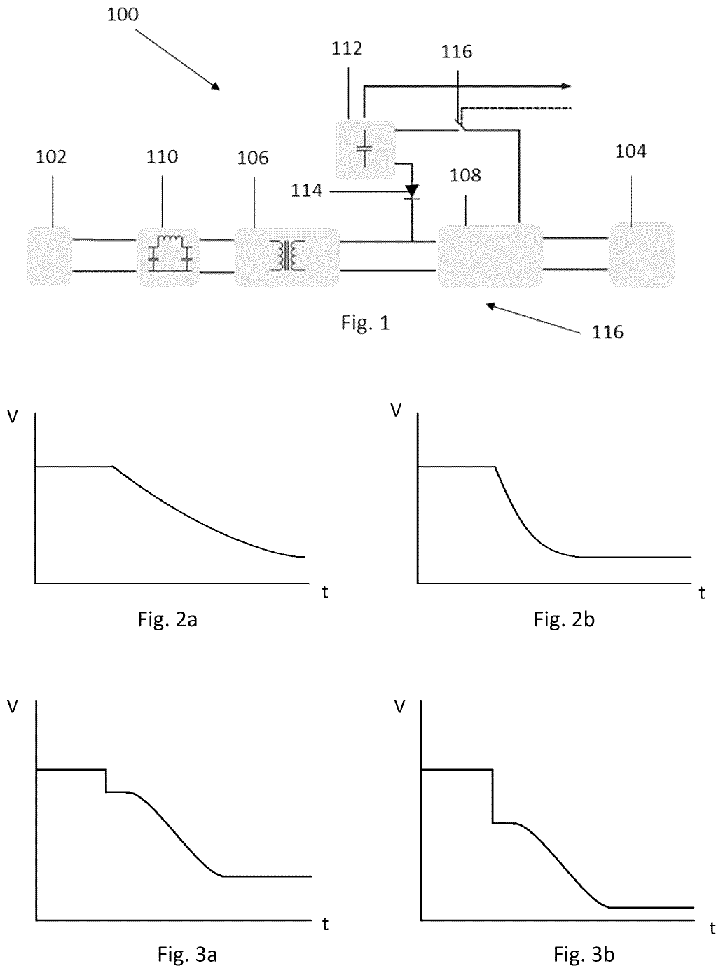

With reference to FIG. 1, a power supply circuit 100 comprises a main energy source 102, an output 104, and a series connection 116 between the main energy source 102 and the output 104. The main energy source 102 supplies electrical energy to the output 104 via the series connection 116.

The series connection 116 includes a first voltage converter 106 and a second voltage converter 108. The first voltage converter 106, e.g. a flyback converter, is connected in series with the main energy source 102, and steps up the voltage supplied by the main energy source 102. Similarly, the second energy converted 108, e.g. a buck converter, is connected in series with the first voltage converter 106 and the output 104, and steps down the voltage supplied by the first voltage converter 106.

An Electromagnetic Capability (EMC) filter 110 is connected in series between the main energy source 102 and the first voltage converter 106. The EMC filter 110 serves to both attenuate conducted noise generated by the power supply circuit 100 and also protect the power supply circuit 100 from external electromagnetic interference. In other arrangements, the EMC filter 100 may be connected in series between any other component, or may be connected in parallel across one or more components.

In some embodiments, one or more additional components may be connected in series between the main energy source 102 and the output 104.

As illustrated in FIG. 1, an energy storage device 112 is connected in parallel to the series connection 116. More specifically, the energy storage device 112 is connected in parallel with the first voltage converter 106 and the second voltage converter 108.

The energy storage device 112 comprises a hold-up energy storage device that provides the output 104 with electrical energy in the event of a failure with or interruption of the main energy source 102. In order to prevent the energy storage device 112 from continuously supplying the output 104 with electrical energy, a diode 114 is located between the energy storage device 112 and the first voltage converter 106. The voltage that can be supplied from the energy storage device 112 is selected so that while the main energy source 102 is supplying electrical energy to the output 104, the diode 114 is reverse-biased. This occurs when the voltage supplied from the main energy source 102 is greater than the voltage supplied by the energy storage device 112. When there is a failure of the main energy source 102, i.e. when the voltage supplied from the main energy source 102 decreases below the selected voltage, the energy storage device 112 supplies electrical energy to the output 104 via the diode 114.

During a charging mode, the energy storage device 112 is charged by the main energy source 102 via the second voltage converter 108. The second voltage converter 108 comprises windings that allows the second voltage converter 108 to provide the energy storage device 112 with a higher voltage than the output 104.

In order to prevent the energy storage device 112 from continuously being charged, a switch 116 is provided between the second voltage converter 108 and the energy storage device 112. While the energy storage device 112 is charging, the switch 116 is closed. When the energy storage device 112 has charged to a maximum capacity and/or a predetermined capacity, i.e. when no more charging is required, the switch 116 is open. The switch is also open during monitoring and/or testing of the energy storage device 112 as described below.

Degradation of the energy storage device 112 may result in loss of hold-up capability or a failure of the power supply circuit 100 in the event of interruption or failure with the main energy source 102. As such, when the energy storage device 112 is not supplying energy to the output 104 and when the energy storage device 112 is not being charged, a controller (not shown) monitors and/or tests the energy storage device 112 for degradation.

During monitoring and/or testing of the energy storage device 112, a fixed load, e.g. a resistor (not shown), is connected across the energy storage device 112. The controller then measures the rate at which the energy storage device 112 discharges.

FIG. 2a shows the rate of discharge of an energy storage device 112 that has not degraded, while FIG. 2b shows the rate of discharge of an energy storage device 112 that has degraded. As illustrated in FIGS. 2a-2b, when the energy storage device 112 has degraded, the rate at which the energy storage device 112 discharges increases.

The controller determines whether the rate at which the energy storage device 112 discharges is within a threshold rate of discharge. If the rate at which the energy storage device discharges 112 is within the threshold rate of discharge, the controller determines that the energy storage device 112 has not degraded. However, if the rate at which the energy storage device 112 discharges is greater than the threshold rate of discharge, the controller determines that the energy storage device 112 has degraded.

The threshold rate of discharge may be based on the fixed load. The threshold rate of discharge may be a maximum rate of discharge before failure of the energy storage device 112 occurs.

In alternative embodiments, the controller measures the effective series resistance (ESR) of the energy storage device 112 when a pulsed load is connected across the energy storage device 112. The term pulsed load refers to a load that is applied instantaneously, then disconnected. In these embodiments, the pulsed load is a pulsed heavy load.

FIG. 3a shows the rate of discharge of an energy storage device 112 that has not degraded, while FIG. 3b shows the rate of discharge of an energy storage device 112 that has degraded. The size of the voltage drop indicates the effective series resistance of the energy storage device 112. As illustrated in FIGS. 3a-3b, when the energy storage device 112 has degraded, the effective series resistance of the energy storage device 112 increases.

The controller determines whether the effective series resistance of the energy storage device 112 is within a threshold effective series resistance. If the effective series resistance of the energy storage device 112 is within the threshold effective series resistance, the controller determines that the energy storage device 112 has not degraded. However, if the effective series resistance of the energy storage device 112 is greater than the threshold effective series resistance, the controller determines that the energy storage device 112 has degraded.

The threshold effective series resistance may be based on a voltage change of the energy storage device 112 when the energy storage device is connected to the pulsed load. The voltage change may be an instantaneous voltage change, i.e. a voltage drop. The threshold effective series resistance may be a maximum effective series resistance before failure of the energy storage device 112 occurs.

In alternative embodiments, the controller measures a change in an energy level and/or a voltage of the energy storage device 112 when no load is connected across the energy storage device 112, i.e. to monitor leakage. When the energy storage device 112 has degraded, the change in the energy level and/or voltage of the energy storage device 112 increases.

The controller determines whether the change in the energy level and/or voltage of the energy storage device 112 is within a threshold value. If the change of the energy level and/or voltage of the energy storage device 112 is within the threshold value, the controller determines that the energy storage device 112 has not degraded. However, if the change in the energy level and/or voltage of the energy storage device 112 is greater than the threshold value, the controller determines that the energy storage device 112 has degraded. The threshold value may be based on a maximum change in the energy level and/or voltage of the energy storage device before failure of the energy storage device 112 occurs.

If it is determined that the energy storage device 112 has not yet degraded, the controller predicts a remaining life of the energy storage device, i.e. the controller predicts when the energy storage device 112 will degrade, based on the monitoring and/or testing.

For example, the controller may compare the rate at which the energy storage device 112 discharges to an initial rate of discharge. Based on a difference between the rate at which the energy storage device 112 discharges and the initial rate of discharge, the controller may predict the time it will take (i.e. the expected useful lifetime of the energy storage device 112) for the rate of discharge of the energy storage device 112 to reach the threshold rate of discharge through degradation. The initial rate of discharge may be the rate at which the energy storage device discharges during an initial monitoring and/or testing of the energy storage device.

In other embodiments, the controller may compare the effective series resistance of the energy storage device 112 to an initial effective series resistance. Based on a difference between the effective series resistance of the energy storage device 112 and the initial effective series resistance, the controller may predict the time (i.e. the expected useful lifetime of the energy storage device 112) it will take for the effective series resistance of the energy storage device 112 to reach the threshold effective series resistance through degradation. The initial effective series resistance may be the effective series resistance of the energy storage device during an initial monitoring and/or testing of the energy storage device.

Alternatively, the controller may compare the change in the energy level and/or voltage of the energy storage device 112 to an initial value. Based on a difference between the change in the energy level and/or voltage of the energy storage device 112 and the initial value, the controller may predict the time (i.e. the expected useful lifetime of the energy storage device 112) it will take for the change in the energy level and/or voltage of the energy storage device 112 to reach the threshold value through degradation. The initial value may be the change in the energy level and/or voltage of the energy storage device during an initial monitoring and/or testing of the energy storage device.

Various aspects of the power supply circuit disclosed in the various embodiments may be used alone, in combination, or in a variety of arrangements not specifically discussed in the embodiments described in the foregoing and this disclosure is therefore not limited in its application to the details and arrangement of components set forth in the foregoing description or illustrated in the drawings. For example, aspects described in one embodiment may be combined in any manner with aspects described in other embodiments. Although particular embodiments have been shown and described, it will be obvious to those skilled in the art that changes and modifications may be made without departing from the invention in its broader aspects. The scope of the following claims should not be limited by the embodiments set forth in the examples, but should be given the broadest reasonable interpretation consistent with the description as a whole.

1. A power supply circuit comprising:
a series connection, the series connection being configured to transmit energy from a main energy source to an output;
an energy storage device connected in parallel to the series connection, the energy storage device being chargeable via the main energy source during a charging mode, the energy storage device being configured to supply energy to the output during a failure of the main energy source; and
a controller configured to monitor or test the energy storage device for degradation when the energy storage device is not supplying energy to the output and when the energy storage device is not being charged.

2. A power supply circuit as claimed in claim 1, wherein the controller is configured to monitor or test the energy storage device by measuring the rate at which the energy storage device discharges when the energy storage device is connected to a fixed load.

3. A power supply circuit as claimed in claim 2, wherein the controller is configured to determine whether the rate at which the energy storage device discharges is within a threshold rate of discharge.

4. A power supply circuit as claimed in claim 3, wherein the controller is configured to determine that the energy storage device is degrading when the rate at which the energy storage device discharges is greater than the threshold rate of discharge.

5. A power supply circuit as claimed claim 1, wherein the controller is configured to monitor and/or test the energy storage device by measuring the effective series resistance of the energy storage device when the energy storage device is connected to a pulsed load.

6. A power supply circuit as claimed in claim 5, wherein the controller is configured to determine whether the effective series resistance is within a threshold effective series resistance.

7. A power supply circuit as claimed in claim 6, wherein the controller is configured to determine that the energy storage device is degrading when the effective series resistance of the energy storage device is greater than the threshold effective series resistance.

8. A power supply circuit as claimed in claim 1, wherein the controller is configured to monitor and/or test the energy storage device by measuring a change in an energy level and/or a voltage of the energy storage device when no load is connected across the energy storage device.

9. A power supply circuit as claimed in claim 8, wherein the controller is configured to determine that the energy storage device is degrading when the change in the energy level and/or voltage of the energy storage device is greater than a threshold value.

10. A power supply circuit as claimed in claim 1, wherein the controller is configured to predict a remaining life of the energy storage device based on the monitoring or testing.

11. A power supply circuit as claimed in claim 1, wherein the energy storage device is connected in parallel to the series connection via a diode, the diode being configured to prevent the energy storage device from supplying energy to the output when there is no failure of the main energy source.

12. A power supply circuit as claimed in claim 1, wherein the energy storage device is connected in parallel to the series connection via a switch, wherein the switch is closed during the charging mode, and wherein the switch is open when the energy storage device is not being charged.

13. A power supply circuit as claimed in claim 1, further comprising:
a first voltage converter and a second voltage converter connected in series, the energy storage device being connected in parallel to the first voltage converter and the second voltage converter.

14. A power supply circuit as claimed in claim 13, wherein the first voltage converter and the second voltage converter are configured to step down the voltage supplied by the main energy source.

15. A power supply circuit as claimed in claim 1, wherein the energy storage device is supplied with a higher voltage than the output.
